(19) United States
(12) Patent Application Publication
(10) Pub. No.: US 2025/0370340 A1
(43) Pub. Date: Dec. 4, 2025

(54) METHOD FOR MANUFACTURING SEMICONDUCTOR SUBSTRATE, COMPOSITION, AND POLYMER

(71) Applicant: JSR CORPORATION, Tokyo (JP)

(72) Inventors: Shuhei YAMADA, Tokyo (JP); Takashi TSUJI, Tokyo (JP); Hiroki NAKATSU, Tokyo (JP); Takashi KATAGIRI, Tokyo (JP); Shinya ABE, Tokyo (JP)

(73) Assignee: JSR CORPORATION, Tokyo (JP)

(21) Appl. No.: 19/247,135

(22) Filed: Jun. 24, 2025

Related U.S. Application Data
(63) Continuation-in-part of application No. PCT/JP2023/044550, filed on Dec. 13, 2023.

(30) Foreign Application Priority Data
Dec. 26, 2022 (JP) 2022-208274

(51) Int. Cl. G03F 7/038; C08G 61/02; G03F 7/09; G03F 7/36; H01L 21/311

(52) U.S. Cl. CPC G03F 7/0388; C08G 61/02; G03F 7/094; G03F 7/36; H01L 21/31138; H01L 21/31144; C08G 2261/124; C08G 2261/1422; C08G 2261/312; C08G 2261/314; C08G 2261/3142; C08G 2261/3323; C08G 2261/3325; C08G 2261/72

(57) ABSTRACT

A method for manufacturing a semiconductor substrate, includes applying a composition for forming a resist underlayer film directly or indirectly to a substrate to form a resist underlayer film. The composition for forming a resist underlayer film includes: a polymer including a repeating unit represented by formula (1); and a solvent. Ar¹ is a divalent group having an aromatic ring structure having 5 to 40 ring atoms, Z is a divalent group having an alicyclic structure having 3 to 20 carbon atoms, and at least one of Ar¹ or Z comprises at least one group selected from the group consisting of a group represented by formula (2-1) and a group represented by formula (2-2). R⁷ is each independently a divalent organic group having 1 to 20 carbon atoms or a single bond, and * is a bond with another structure in the polymer.

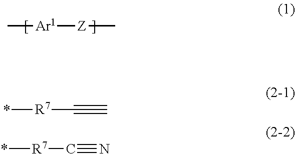

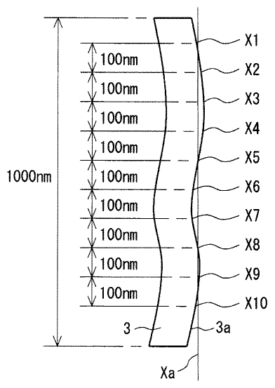

### CROSS-REFERENCE TO RELATED APPLICATIONS

The present application is a continuation-in-part application of International Patent Application No. PCT/JP2023/044550 filed Dec. 13, 2023, which claims priority to Japanese Patent Application No. 2022-208274 filed Dec. 26, 2022. The contents of these applications are incorporated herein by reference in their entirety.

### BACKGROUND OF THE DISCLOSURE

### Technical Field

The present disclosure relates to a method for manufacturing a semiconductor substrate, a composition, and a polymer.

### Background Art

A semiconductor device is produced using, for example, a multilayer resist process in which a resist pattern is formed by exposing and developing a resist film laminated on a substrate with a resist underlayer film, such as an organic underlayer film or a silicon-containing film, being interposed between them. In this process, the resist underlayer film is etched using this resist pattern as a mask, and the substrate is further etched using the obtained resist underlayer film pattern as a mask so that a desired pattern is formed on the semiconductor substrate (see JP-A-2004-177668).

Various studies have been conducted on materials to be used for such a composition for forming a resist underlayer film (see WO 2011/108365 A).

### SUMMARY

According to an aspect of the present disclosure, a method for manufacturing a semiconductor substrate, includes: applying a composition for forming a resist underlayer film directly or indirectly to a substrate to form a resist underlayer film; forming a resist pattern directly or indirectly on the resist underlayer film; and performing etching using the resist pattern as a mask. The composition for forming a resist underlayer film includes: a polymer including a repeating unit represented by formula (1) (hereinafter also referred to as a “polymer (A)”); and a solvent (hereinafter also referred to as a “solvent (B)”). Ar¹ is a divalent group having an aromatic ring structure having 5 to 40 ring atoms, Z is a divalent group having an alicyclic structure having 3 to 20 carbon atoms, and at least one of Ar¹ or Z comprises at least one group selected from the group consisting of a group represented by formula (2-1) and a group represented by formula (2-2). R⁷ is each independently a divalent organic group having 1 to 20 carbon atoms or a single bond, and * is a bond with another structure in the polymer.

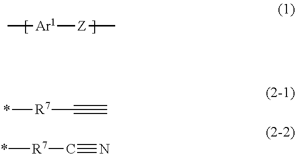

According to another aspect of the present disclosure, a composition includes: a polymer including a repeating unit represented by formula (1); and a solvent. Ar¹ is a divalent group having an aromatic ring structure having 5 to 40 ring atoms, Z is a divalent group having an alicyclic structure having 3 to 20 carbon atoms, and at least one of Ar¹ or Z comprises at least one group selected from the group consisting of a group represented by formula (2-1) and a group represented by formula (2-2). R⁷ is each independently a divalent organic group having 1 to 20 carbon atoms or a single bond, and * is a bond with another structure in the polymer.

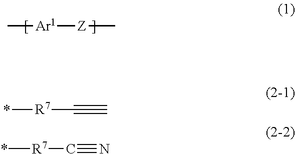

According to a further aspect of the present disclosure, a polymer includes a repeating unit represented by formula (1). Ar¹ is a divalent group having an aromatic ring structure having 5 to 40 ring atoms, Z is a divalent group having an alicyclic structure having 3 to 20 carbon atoms, and at least one of Ar¹ or Z has at least one group selected from the group consisting of a group represented by formula (2-1) and a group represented by formula (2-2). R⁷ is each independently a divalent organic group having 1 to 20 carbon atoms or a single bond, and * is a bond with another structure in the polymer.

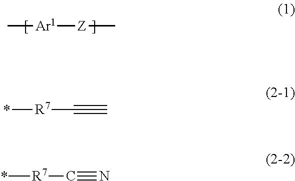

### BRIEF DESCRIPTION OF THE DRAWINGS

The FIGURE is a schematic plan view for explaining a method for evaluating bending resistance.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

In a multilayer resist process, an organic underlayer film as a resist underlayer film is required to have heat resistance, and bending resistance.

In the present specification, the term “ring members” refers to the number of atoms constituting the ring. For example, a biphenyl ring has 12 ring members, a naphthalene ring has 10 ring members, and a fluorene ring has 13 ring members.

According to the method for manufacturing a semiconductor substrate, a resist underlayer film excellent in heat resistance and bending resistance is formed, and therefore, a favorable semiconductor substrate can be obtained. According to the composition, a film excellent in heat resistance and bending resistance can be formed. The polymer is suitable for a composition that can be used to form a film excellent in heat resistance and bending resistance. Therefore, they can suitably be used for, for example, producing semiconductor devices expected to be further microfabricated in the future.

Hereinafter, a method for manufacturing a semiconductor substrate, a composition, and a polymer according to embodiments of the present disclosure will be described in detail. Combinations of preferred aspects in the embodiments are also preferred.

### Method for Manufacturing Semiconductor Substrate

The method for manufacturing a semiconductor substrate includes:
applying a composition for forming a resist underlayer film directly or indirectly to a substrate (hereinafter also referred to as an “applying step”);
forming a resist pattern directly or indirectly on the resist underlayer film formed by the applying step (hereinafter also referred to as a “resist pattern forming step”); and
performing etching using the resist pattern as a mask (hereinafter also referred to as an “etching step”).

According to the method for manufacturing a semiconductor substrate, a resist underlayer film superior in heat resistance and bending resistance can be formed due to the use of the composition described later as a composition for forming a resist underlayer film in the applying step, so that a semiconductor substrate having a favorable pattern configuration can be manufactured.

The method for manufacturing a semiconductor substrate may further include, as necessary, a step of forming a silicon-containing film directly or indirectly on the resist underlayer film before the formation of the resist pattern (hereinafter also referred to as “silicon-containing film forming step”).

Hereinafter, the composition to be used in the method for manufacturing a semiconductor substrate and the respective steps will be described.

### Composition

The composition includes a polymer [A] and a solvent [B]. The composition may include an optional component as long as the effect of the composition is not impaired.

Owing to containing the polymer [A] and the solvent [B], the composition can form a film superior in heat resistance, and bending resistance. Accordingly, the composition can be used as a composition for forming a film. Specifically, the composition can be suitably used a composition for forming a resist underlayer film in a multilayer resist process.

Each component contained in the composition will be described below.

### Polymer [A]

The polymer [A] has a repeating unit represented by formula (1). The polymer [A] may have two or more types of repeating units represented by formula (1). The composition can contain one kind or two or more kinds of the polymer [A].

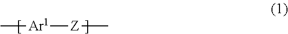

In the formula (1), Ar¹ is a divalent group having an aromatic ring structure having 5 to 40 ring atoms. Z is a divalent group having an alicyclic structure having 3 to 20 carbon atoms. At least one of Ar¹ or Z has at least one group selected from the group consisting of a group represented by formula (2-1) and a group represented by formula (2-2).

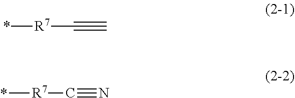

In the formulas (2-1) and (2-2), R⁷ is each independently a divalent organic group having 1 to 20 carbon atoms or a single bond. * is a bond with another structure in the polymer.

Z in the formula (1) is preferably represented by formula (A).

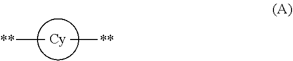

In the formula (A), Cy is the alicyclic structure. ** are each a bond, which extends from a carbon atom constituting an alicyclic structure, with another structure in the polymer.

It is preferable that at least one of the bonds of Z in the formula (1) is bonded to Ar¹ at a carbon atom constituting the alicyclic structure in Z, it is more preferable that, for both bonds of Z in the formula (1), a carbon atom constituting the alicyclic structure in Z is bonded to Ar¹.

In the formula (1), examples of the aromatic ring structure having 5 to 40 ring atoms in Ar¹ and R⁰ include aromatic hydrocarbon rings such as a benzene ring, a naphthalene ring, an anthracene ring, a phenalene ring, a phenanthrene ring, a pyrene ring, a fluorene ring, a perylene ring, and a coronene ring; aromatic heterocycles such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, a triazine group, a carbazole ring, and a dibenzofuran ring, or combinations thereof. The aromatic ring structure of the Ar¹ and R⁰ is preferably at least one aromatic hydrocarbon ring selected from the group consisting of a benzene ring, a naphthalene ring, an anthracene ring, a phenalene ring, a phenanthrene ring, a pyrene ring, a fluorene ring, a perylene ring, and a coronene ring.

In the formula (1), suitable examples of the divalent group having an aromatic ring structure having 5 to 40 ring atoms represented by Ar¹ include a group obtained by removing two hydrogen atoms from the aromatic ring having 5 to 40 ring atoms in the Ar¹.

In the formula (1), examples of the alicyclic structure having 3 to 20 carbon atoms in Z include monocyclic saturated hydrocarbon rings such as a cyclopropane ring, a cyclobutane ring, a cyclopentane ring, and a cyclohexane ring; monocyclic unsaturated hydrocarbon rings such as a cyclopropene ring, a cyclobutene ring, a cyclopentene ring, and a cyclohexene ring; polycyclic saturated hydrocarbon rings such as a norbornane ring, an adamantane ring, a bicyclooctane ring, a bicyclodecane ring, and a tetrahydrodicyclopentadiene ring; polycyclic unsaturated hydrocarbon group rings such as a norbornene ring and a dicyclopentadiene ring; and spiro hydrocarbon rings such as a spirodecane ring and a spiroundecane ring. The alicyclic structure of Z is preferably at least one alicyclic hydrocarbon ring selected from the group consisting of a cyclobutane ring, a cyclopentane ring, a cyclohexane ring, a norbornane ring, an adamantane ring, a bicyclooctane ring, and a tetrahydrodicyclopentadiene ring.

From the viewpoint of heat resistance, the alicyclic structure is preferably an alicyclic saturated hydrocarbon ring.

In the formula (1), suitable examples of the divalent group having an alicyclic structure having 3 to 20 carbon atoms represented by Z include a group obtained by removing two hydrogen atoms from the alicyclic structure having 3 to 20 carbon atoms in Z.

It is preferable that at least one of the aromatic ring structure or the alicyclic structure has a polycyclic structure from the viewpoint that the structure of the polymer [A] becomes rigid and the heat resistance and bending resistance are improved. The aromatic ring structure of Ar¹ is more preferably a naphthalene ring, a pyrene ring, or a fluorene ring. The alicyclic structure of Z is more preferably a norbornane ring, an adamantane ring, or a tetrahydrodicyclopentadiene ring.

In the formulas (2-1) and (2-2), examples of the divalent organic group having 1 to 20 carbon atoms represented by R⁷ include a divalent hydrocarbon group having 1 to 20 carbon atoms, a group containing a divalent heteroatom-containing group between two carbon atoms of the foregoing hydrocarbon group, a group obtained by substituting some or all of the hydrogen atoms of the foregoing hydrocarbon group with a monovalent heteroatom-containing group, and a combination thereof.

Examples of the divalent hydrocarbon group having 1 to 20 carbon atoms include divalent chain hydrocarbon groups having 1 to 20 carbon atoms, divalent alicyclic hydrocarbon groups having 3 to 20 carbon atoms, divalent aromatic hydrocarbon groups having 6 to 20 carbon atoms, and combinations thereof.

As used herein, the “hydrocarbon group” includes a chain hydrocarbon group, an alicyclic hydrocarbon group, and an aromatic hydrocarbon group. The “hydrocarbon group” includes a saturated hydrocarbon group and an unsaturated hydrocarbon group. The “chain hydrocarbon group” means a hydrocarbon group that contains no cyclic structure and is composed only of a chain structure, and includes both a linear hydrocarbon group and a branched hydrocarbon group. The “alicyclic hydrocarbon group” means a hydrocarbon group that contains only an alicyclic structure as a ring structure and contains no aromatic ring structure, and includes both a monocyclic alicyclic hydrocarbon group and a polycyclic alicyclic hydrocarbon group (however, the alicyclic hydrocarbon group is not required to be composed of only an alicyclic structure, and may contain a chain structure as a part thereof). The “aromatic hydrocarbon group” means a hydrocarbon group containing an aromatic ring structure as a ring structure (however, the aromatic hydrocarbon group is not required to be composed of only an aromatic ring structure, and may contain an alicyclic structure or a chain structure as a part thereof).

Examples of the divalent chain hydrocarbon group having 1 to 20 carbon atoms include a methanediyl group, an ethanediyl group, a propanediyl group, a butanediyl group, a hexanediyl group, and an octanediyl group. In particular, an alkanediyl group having 1 to 8 carbon atoms is preferable.

Examples of the divalent alicyclic hydrocarbon group having 3 to 20 carbon atoms include cycloalkanediyl groups such as a cyclopentanediyl group and a cyclohexanediyl group; cycloalkenediyl groups such as a cyclopentenediyl group and a cyclohexenediyl group; bridged cyclic saturated hydrocarbon groups such as a norbornanediyl group, an adamantanediyl group, and a tricyclodecanediyl group; and bridged cyclic unsaturated hydrocarbon groups such as a norbornenediyl group and a tricyclodecenediyl group.

Examples of the divalent aromatic hydrocarbon group having 6 to 20 carbon atoms include a phenylene group, a naphthalenediyl group, an anthracenediyl group, a pyrenediyl group, a toluenediyl group, and a xylenediyl group.

Examples of heteroatoms that constitute divalent or monovalent heteroatom-containing groups include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom.

Examples of the divalent heteroatom-containing group include —CO—, —CS—, —NH—, —O—, —S—, and groups obtained by combining them.

Examples of the monovalent heteroatom-containing group include a hydroxy group, a sulfanyl group, a cyano group, a nitro group, and halogen atoms.

As R⁷, a divalent hydrocarbon group having 1 to 10 carbon atoms such as a methanediyl group, an ethanediyl group, and a phenylene group, —O—, and a combination thereof are preferable, and a methanediyl group, an ethanediyl group, a combination of a methanediyl group with —O—, or a combination of an ethanediyl group with —O— is more preferable.

In the formulas (2-1) and (2-2), the bonding target of the bond represented by * is preferably a carbon atom constituting the aromatic ring structure and a carbon atom constituting the alicyclic structure, more preferably a carbon atom constituting the aromatic ring structure.

Ar¹ preferably has at least one group (hereinafter also referred to as “group (α)”) selected from the group consisting of a group represented by the formula (2-1) and a group represented by the formula (2-2), and more preferably has two or more of the groups (α). The upper limit of the number of groups (α) contained in Ar¹ is preferably four, more preferably three. This makes it possible to further improve the heat resistance and bending resistance of the resist underlayer film to be formed.

It is preferable that Ar¹ has a group represented by the formula (2-1), and the group is represented by formula (2-1-1) or (2-1-2).

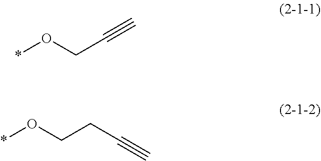

In the formula (2-1-1) or formula (2-1-2), * is a bond with a carbon atom constituting the aromatic ring structure.

Ar¹ and Z may have a substituent other than a group represented by formula (2-1) and a group represented by formula (2-2). Examples of the substituent include monovalent chain hydrocarbon groups having 1 to 10 carbon atoms, halogen atoms such as a fluorine atom, a chlorine atom, a bromine atom, and an iodine atom, alkoxy groups such as a methoxy group, an ethoxy group, and a propoxy group, aryloxy groups such as a phenoxy group and a naphthyloxy group, alkoxycarbonyl groups such as a methoxycarbonyl group and an ethoxycarbonyl group, alkoxycarbonyloxy groups such as a methoxycarbonyloxy group and an ethoxycarbonyloxy group, acyl groups such as a formyl group, an acetyl group, a propionyl group, and a butyryl group, a cyano group, hydroxy group and a nitro group.

Examples of the repeating unit represented by the formula (1) include repeating units represented by formulas (1-1) to (1-18).

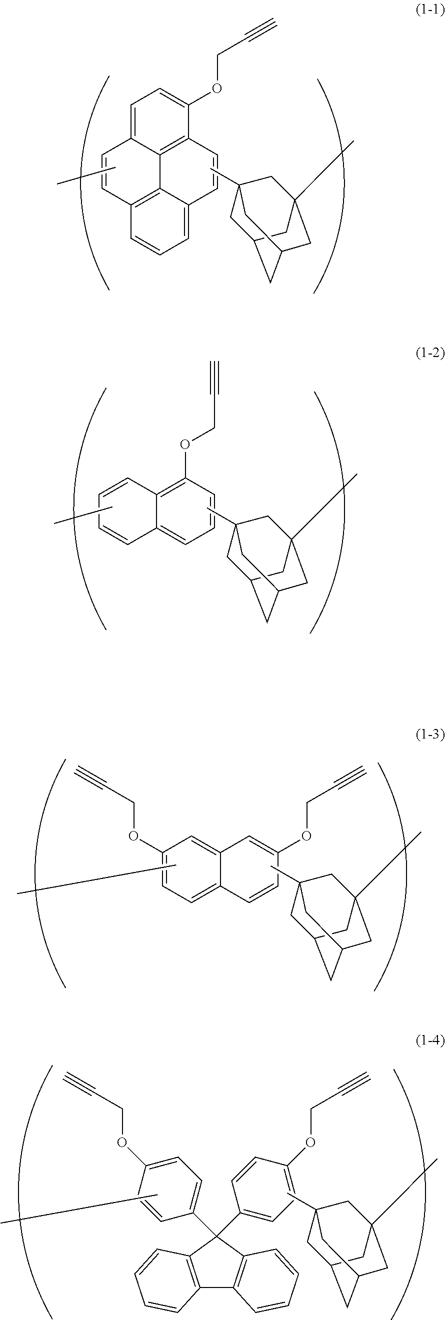

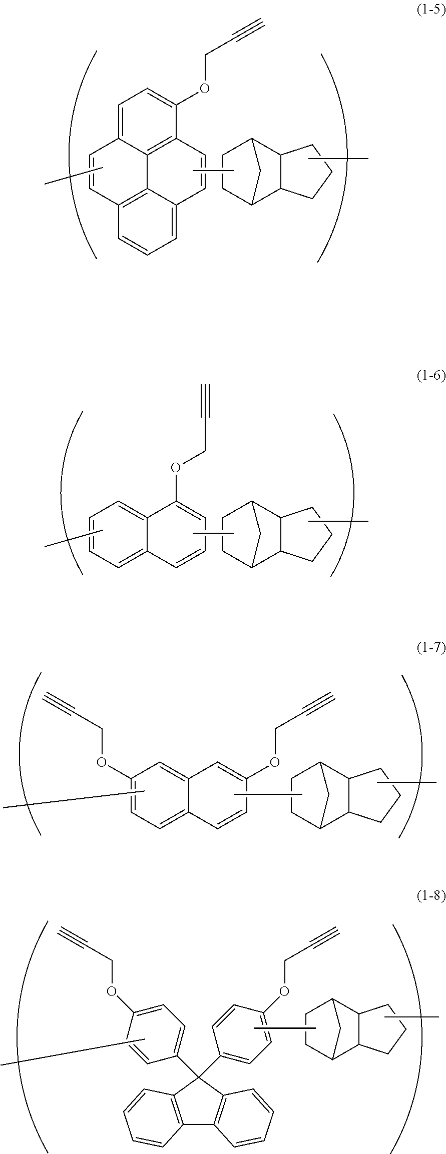

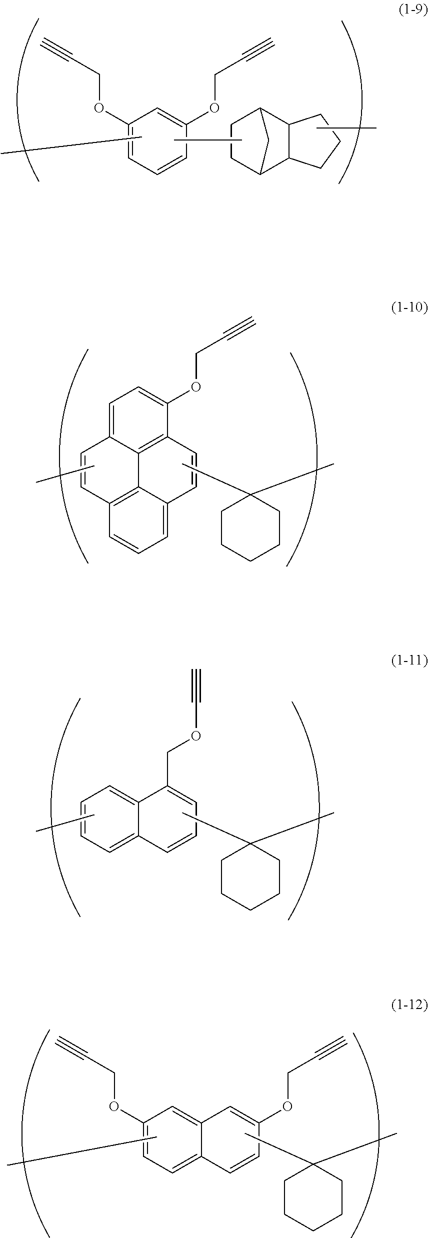

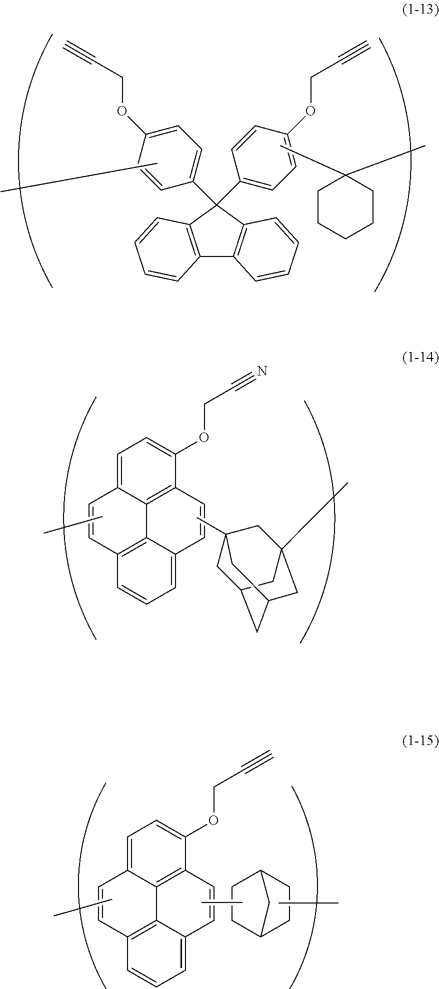

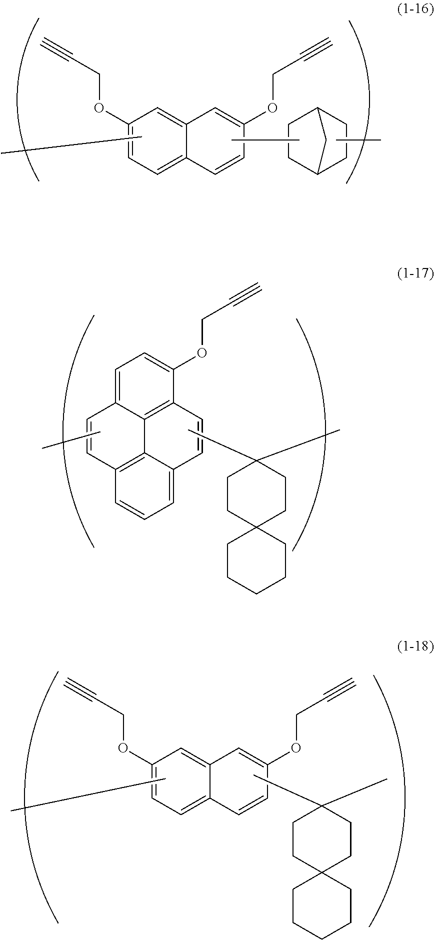

Among these, the repeating units represented by the formulas (1-1) to (1-14) are preferable, and the repeating units represented by the formulas (1-1), (1-3) to (1-5), (1-7) to (1-9), and (1-11) to (1-14) are more preferable.

The lower limit of the weight average molecular weight of the polymer [A] is preferably 800, more preferably 1200, still more preferably 1600, and particularly preferably 2000. The upper limit of the molecular weight is preferably 10000, more preferably 8000, still more preferably 6000, and particularly preferably 5000. The weight average molecular weight is measured as described in EXAMPLES.

The lower limit of content of the polymer [A] in the composition is preferably 2% by mass, more preferably 48 by mass, still more preferably 6% by mass, particularly preferably 8% by mass based on the total mass of the polymer [A] and the solvent [B]. The upper limit of the content is preferably 30% by mass, more preferably 25% by mass, still more preferably 20% by mass, particularly preferably 15% by mass based on the total mass of the polymer [A] and the solvent [B].

### Method for Producing Polymer [A]

Typically, the polymer [A] can be produced through acid addition condensation between an aromatic ring compound having a phenolic hydroxy group as a precursor to afford Ar¹ of the formula (1) and an alicyclic compound having a hydroxy group, a structure in which a hydroxy group is bonded to the α-position of unsaturated bond carbon, or a ketone structure as a precursor to afford Z in the formula (1) in the presence of an acid catalyst and a subsequent nucleophilic substitution reaction by a phenolic hydroxy group to halogenated hydrocarbon corresponding to the group represented by the formula (2-1) or (2-2). An acid catalyst is not particularly limited, and publicly known inorganic acids and organic acids can be used. After the reaction, the polymer [A] can be obtained through separation, purification, drying, and the like. As the reaction solvent, the solvent [B] described later can be suitably employed.

### Solvent [B]

The solvent [B] is not particularly limited as long as it can dissolve or disperse the polymer [A] and optional components contained as necessary.

Examples of the solvent [B] include a hydrocarbon-based solvent, an ester-based solvent, an alcohol-based solvent, a ketone-based solvent, an ether-based solvent, and a nitrogen-containing solvent. The solvent [B] may be used singly or two or more kinds thereof may be used in combination.

Examples of the hydrocarbon-based solvent include aliphatic hydrocarbon-based solvents such as n-pentane, n-hexane, and cyclohexane, and aromatic hydrocarbon-based solvents such as benzene, toluene, and xylene.

Examples of the ester-based solvent include carbonate-based solvents such as diethyl carbonate, acetic acid monoacetate ester-based solvents such as methyl acetate and ethyl acetate, lactone-based solvents such as γ-butyrolactone, polyhydric alcohol partial ether carboxylate-based solvents such as diethylene glycol monomethyl ether acetate and propylene glycol monomethyl ether acetate, and lactate ester-based solvents such as methyl lactate and ethyl lactate.

Examples of the alcohol-based solvent include monoalcohol-based solvents such as methanol, ethanol, and n-propanol, and polyhydric alcohol-based solvents such as ethylene glycol and 1,2-propylene glycol.

Examples of the ketone-based solvent include chain ketone-based solvents such as methyl ethyl ketone and methyl isobutyl ketone, and cyclic ketone-based solvents such as cyclohexanone.

Examples of the ether-based solvent include chain ether-based solvents such as n-butyl ether, cyclic ether-based solvents such as tetrahydrofuran, polyhydric alcohol ether-based solvents such as propylene glycol dimethyl ether, and polyhydric alcohol partial ether-based solvents such as diethylene glycol monomethyl ether.

Examples of the nitrogen-containing solvent include chain nitrogen-containing solvents such as N,N-dimethylacetamide, and cyclic nitrogen-containing solvents such as N-methylpyrrolidone.

As the solvent [B], an ester-based solvent or a ketone-based solvent is preferable, a polyhydric alcohol partial ether carboxylate-based solvent or a cyclic ketone-based solvent is more preferable, and propylene glycol monomethyl ether acetate or cyclohexanone is still more preferable.

The lower limit of the content ratio of the solvent [B] in the composition is preferably 60% by mass, more preferably 70% by mass, and still more preferably 80% by mass. The upper limit of the content ratio is preferably 99.9% by mass, more preferably 99% by mass, and still more preferably 95% by mass.

### Optional Component

The composition may include an optional component as long as the effect of the composition is not impaired. Examples of the optional component include an acid generator, a crosslinking agent, and a surfactant. The optional component may be used singly or two or more kinds thereof may be used in combination. The content ratio of the optional component in the composition can be appropriately determined according to the type and the like of the optional component.

### Method for Preparing Composition

The composition can be prepared by mixing the polymer [A], the solvent [B] and, as necessary, an optional component in a prescribed ratio and preferably filtering the resulting mixture through a membrane filter having a pore size of 0.5 μm or less and the like.

### Applying Step

In this step, a composition for forming a resist underlayer film is applied directly or indirectly to a substrate. In this step, the above-mentioned composition is used as a composition for forming a resist underlayer film.

The method of the application of the composition for forming a resist underlayer film is not particularly limited, and the application can be performed by an appropriate method such as spin coating, cast coating, or roll coating. As a result, a coating film is formed, and volatilization of the solvent [B] or the like occurs, so that a resist underlayer film is formed.

Examples of the substrate include metallic or semimetallic substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

Examples of the case where the composition for forming a resist underlayer film is applied indirectly to the substrate include a case where the composition for forming a resist underlayer film is applied to a silicon-containing film described later formed on the substrate.

In the present embodiment, a heating step in which the coating film formed through the applying step is heated may be carried out. The formation of the resist underlayer film is promoted by heating the coating film. More specifically, volatilization or the like of the solvent [B] is promoted by heating the coating film.

The heating of the coating film may be performed either in the air atmosphere or in a nitrogen atmosphere. The lower limit of the heating temperature is preferably 100° C., more preferably 150° C., and still more preferably 180° C. The upper limit of the heating temperature is preferably 500° C., more preferably 400° C., and still more preferably 380° C. The lower limit of the heating time is preferably 15 seconds, and more preferably 30 seconds. The upper limit of the time is preferably 1,200 seconds, and more preferably 600 seconds.

After the applying step, the resist underlayer film may be subjected to exposure. After the applying step, the resist underlayer film may be exposed to plasma. After the applying step, the resist underlayer film may be ion-implanted. When the resist underlayer film is exposed, the etching resistance of the resist underlayer film is improved. When the resist underlayer film is exposed to plasma, the etching resistance of the resist underlayer film is improved. When the resist underlayer film is subjected to ion implantation, the etching resistance of the resist underlayer film is improved.

The radiation to be used for exposure of the resist underlayer film is appropriately selected from among electromagnetic waves such as visible rays, ultraviolet rays, far ultraviolet rays, X-rays, and γ-rays and corpuscular rays such as electron beam, molecular beams, and ion beams.

Examples of the method for exposing the resist underlayer film to plasma include a direct method in which a substrate is placed in each gas atmosphere and plasma discharge is performed. As plasma exposure conditions, usually, the gas flow rate is 50 cc/min or more and 100 cc/min or less, and the supply power is 100 W or more and 1,500 W or less.

The lower limit of the time of the exposure to plasma is preferably 10 seconds, more preferably 30 seconds, and still more preferably 1 minute. The upper limit of the time is preferably 10 minutes, more preferably 5 minutes, and still more preferably 2 minutes.

The plasma is generated, for example, under an atmosphere of a mixed gas of H₂ gas and Ar gas. In addition to the H₂ gas and the Ar gas, a carbon-containing gas such as a CF₄ gas or a CH₄ gas may be introduced. At least one among a CF₄ gas, an NF₃ gas, a CHF₃ gas, a CO₂ gas, a CH₂F₂ gas, a CH₄ gas, and a C₄F₈ gas may be introduced instead of one or both of the H₂ gas and the Ar gas.

In the ion implantation into the resist underlayer film, a dopant is implanted into the resist underlayer film. The dopant may be selected from the group consisting of boron, carbon, nitrogen, phosphorus, arsenic, aluminum, and tungsten. The implantation energy utilized to apply a voltage to the dopant may be from about 0.5 keV to 60 keV depending on the type of the dopant to be utilized and a desired depth of implantation.

The lower limit of the average thickness of the resist underlayer film to be formed is preferably 30 nm, more preferably 50 nm, and still more preferably 100 nm. The upper limit of the average thickness is preferably 3,000 nm, more preferably 2,000 nm, and still more preferably 500 nm. The average thickness is measured as described in Examples.

### Silicon-Containing Film Forming Step

In this step, a silicon-containing film is formed directly or indirectly on the resist underlayer film formed through the applying step or the heating step. Examples of the case where the silicon-containing film is formed indirectly on the resist underlayer film include a case where a surface modification film of the resist underlayer film is formed on the resist underlayer film. The surface modification film of the resist underlayer film is, for example, a film having a contact angle with water different from that of the resist underlayer film.

The silicon-containing film can be formed by, for example, application, chemical vapor deposition (CVD), atomic layer deposition (ALD), or the like of a composition for forming a silicon-containing film. Examples of a method for forming a silicon-containing film by application of a composition for forming a silicon-containing film include a method in which a coating film formed by applying a composition for forming a silicon-containing film directly or indirectly to the resist underlayer film is cured by exposure and/or heating. As a commercially available product of the composition for forming a silicon-containing film, for example, “NFC SOG01”, “NFC SOG04”, or “NFC SOG080” (all manufactured by JSR Corporation) can be used. By chemical vapor deposition (CVD) or atomic layer deposition (ALD), a silicon oxide film, a silicon nitride film, a silicon oxynitride film, or an amorphous silicon film can be formed.

Examples of the radiation to be used for the exposure include electromagnetic waves such as visible rays, ultraviolet rays, far ultraviolet rays, X-rays, and γ-rays and corpuscular rays such as electron beam, molecular beams, and ion beams.

The lower limit of the temperature in heating the coating film is preferably 90° C., more preferably 150° C., and still more preferably 200° C. The upper limit of the temperature is preferably 550° C., more preferably 450° C., and still more preferably 300° C. Heating may be carried out in one step or in multiple steps.

The lower limit of the average thickness of the silicon-containing film is preferably 1 nm, more preferably 10 nm, and still more preferably 20 nm. The upper limit is preferably 20,000 nm, more preferably 1,000 nm, and still more preferably 100 nm. The average thickness of the silicon-containing film is a value measured using the spectroscopic ellipsometer in the same manner as for the average thickness of the resist underlayer film.

### Resist Pattern Forming Step

In this step, a resist pattern is formed directly or indirectly on the resist underlayer film. Examples of a method for performing this step include a method using a resist composition, a method using nanoimprinting, and a method using a self-assembly composition. Examples of the case of forming a resist pattern indirectly on the resist underlayer film include a case of forming a resist pattern on the silicon-containing film.

Examples of the resist composition include a positive or negative chemically amplified resist composition containing a radiation sensitive acid generator, a positive resist composition containing an alkali-soluble resin and a quinonediazide-based photosensitizer, a negative resist composition containing an alkali-soluble resin and a crosslinking agent, and a metal-containing resist composition containing metals such as tin, zirconium, and hafnium.

Examples of the method of applying the resist composition include a spin coating method. The temperature and time of the prebaking may be appropriately adjusted according to the type or the like of the resist composition to be used.

Then, the formed resist film is subjected to exposure by selective irradiation with radiation. Radiation to be used for the exposure can be appropriately selected according to the type or the like of the radiation-sensitive acid generator to be used in the resist composition, and examples thereof include electromagnetic rays such as visible rays, ultraviolet rays, far-ultraviolet, X-rays, and γ-rays and corpuscular rays such as electron beam, molecular beams, and ion beams. Among these, far-ultraviolet rays are preferable, and KrF excimer laser light (wavelength: 248 nm), ArF excimer laser light (wavelength: 193 nm), F₂ excimer laser light (wavelength: 157 nm), Kr₂ excimer laser light (wavelength: 147 nm), ArKr excimer laser light (wavelength: 134 nm) or extreme ultraviolet rays (wavelength: 13.5 nm, etc., also referred to as “EUV”) are more preferred, and ArF excimer laser light or EUV is even more preferred.

After the exposure, post-baking may be performed to improve resolution, pattern profile, developability, etc. The temperature and time of the post-baking may be appropriately determined according to the type or the like of the resist composition to be used.

Then, the exposed resist film is developed with a developer to form a resist pattern. This development may be either alkaline development or organic solvent development. Examples of the developer for alkaline development include basic aqueous solutions of ammonia, triethanolamine, tetramethylammonium hydroxide (TMAH), and tetraethylammonium hydroxide. To these basic aqueous solutions, for example, a water-soluble organic solvent such as an alcohol, e.g., methanol or ethanol, or a surfactant may be added in an appropriate amount. Examples of the developer for organic solvent development include the various organic solvents recited as examples of the solvent [B] in the composition described above.

After the development with a developer, a prescribed resist pattern is formed through washing and drying.

### Etching Step

In this step, etching is performed using the resist pattern as a mask. The number of times of the etching may be once. Alternatively, etching may be performed a plurality of times, that is, etching may be sequentially performed using a pattern obtained by etching as a mask. From the viewpoint of obtaining a pattern having a favorable shape, etching is preferably performed a plurality of times. When performed a plurality of times, etching is performed to the silicon-containing film, the resist underlayer film, and the substrate sequentially in order. Examples of an etching method include dry etching and wet etching. Dry etching is preferable from the viewpoint of achieving a favorable shape of the pattern of the substrate. In the dry etching, for example, gas plasma such as oxygen plasma is used. As a result of the etching, a semiconductor substrate having a prescribed pattern is obtained.

The dry etching can be performed using, for example, a publicly known dry etching apparatus. The etching gas used for dry etching can be appropriately selected according to the elemental composition of the film to be etched, and for example, fluorine-based gases such as CHF₃, CF₄, C₂F₆, C₃F₈, and SF₆, chlorine-based gases such as Cl₂ and BCl₃, oxygen-based gases such as O₂, O₃, and H₂O, reducing gases such as H₂, NH₃, CO, CO₂, CH₄, C₂H₂, C₂H₄, C₂H₆, C₃H₄, C₃H₆, C₃H₈, HF, HI, HBr, HCl, NO, and BCl₃, and inert gases such as He, N₂ and Ar are used. These gases can also be mixed and used. When the substrate is etched using the pattern of the resist underlayer film as a mask, a fluorine-based gas is usually used.

### Composition

The composition comprises a polymer [A] and a solvent [B]. As the composition, a composition to be used in the above-described method for manufacturing a semiconductor substrate can be suitably employed.

### Polymer

The polymer has a repeating unit represented by the formula (1). As the polymer, the polymer [A] to be used in the method for manufacturing a semiconductor substrate can be suitably employed.

### EXAMPLES

Hereinbelow, the present invention will specifically be described on the basis of examples, but is not limited to these examples.

### Weight-Average Molecular Weight (Mw)

The Mw of a polymer was measured by gel permeation chromatography (detector: differential refractometer) with monodisperse polystyrene standards using GPC columns (“G2000HXL”×2, “G3000HXL”×1 and “G4000HXL”×1) manufactured by Tosoh Corporation under the following analysis conditions: flow rate: 1.0 mL/min; elution solvent: tetrahydrofuran; column temperature: 40° C.

### Average Thickness of Resist Underlayer Film

The average thickness of a film was determined as a value obtained by measuring the film thickness at arbitrary nine points at intervals of 5 cm including the center of the resist underlayer film formed on a silicon wafer using a spectroscopic ellipsometer (“M2000D” available from J. A. WOOLLAM Co.) and calculating the average value of the film thicknesses.

### Synthesis of Polymer [A]

Polymers having repeating units represented by formulas (A-1) to (A-14) and (x-1) to (x-4) (hereinafter, each of them is also referred to as “polymer (A-1)” or the like) were synthesized by the following procedures. In the formulas, when a number is attached to a repeating unit, the number represents the content ratio (mol %) of the repeating unit.

### Synthesis of Precursor of Polymer [A]

### [Synthesis Example 1-1] (Synthesis of Polymer (a-1))

In a nitrogen atmosphere, 5.0 g of 1-hydroxypyrene, 2.5 g of 1,3-adamantanediol, and 21.0 g of dichloroethane were charged into a reaction vessel and dissolved. After, 0.7 g of methanesulfonic acid was added into the reaction vessel, and then the mixture was heated to 90° C. and reacted for 3 hours. After the reaction was completed, the reaction solution was transferred to a separatory funnel, and 50 g of dichloroethane and 200 g of water were added to wash the organic phase. After the aqueous phase was separated, the obtained organic phase was washed several times with 200 g of water and concentrated using an evaporator. The residue was added dropwise to 200 g of methanol to obtain a precipitate. The precipitate was collected by suction filtration and washed several times with 50 g of methanol. Then, the washed product was dried at 60° C. for 12 hours using a vacuum dryer, thereby obtaining a polymer (a-1) represented by formula (a-1). The Mw of the polymer (a-1) was 2,300.

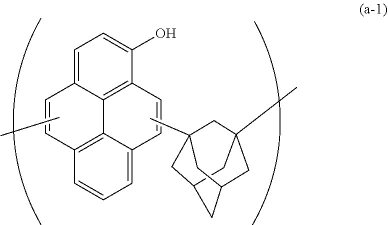

### [Synthesis Example 1-2] (Synthesis of Polymer (a-2))

A polymer (a-2) represented by formula (a-2) was obtained in the same manner as in Synthesis Example 1 except that 5.0 g of 1-hydroxypyrene was changed to 3.3 g of 1-hydroxynaphthalene. The Mw of the polymer (a-2) was 2,800.

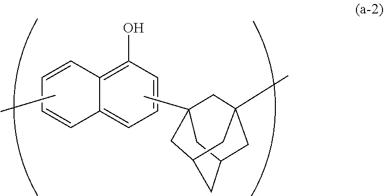

### [Synthesis Example 1-3] (Synthesis of Polymer (a-3))

A polymer (a-3) represented by formula (a-3) was obtained in the same manner as in Synthesis Example 1 except that 5.0 g of 1-hydroxypyrene was changed to 3.7 g of 2,7-dihydroxynaphthalene. The Mw of the polymer (a-3) was 2,400.

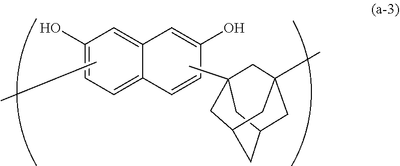

### [Synthesis Example 1-4] (Synthesis of Polymer (a-4))

A polymer (a-4) represented by formula (a-4) was obtained in the same manner as in Synthesis Example 1 except that 5.0 g of 1-hydroxypyrene was changed to 8.1 g of 9,9′-bis(4-hydroxyphenyl)fluorene. The Mw of the polymer (a-4) was 2,000.

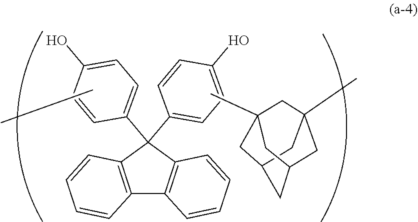

### [Synthesis Example 1-5] (Synthesis of Polymer (a-5))

A polymer (a-5) represented by formula (a-5) was obtained in the same manner as in Synthesis Example 1 except that 1.95 g of 1,3-adamantanediol was changed to 1.75 g of 3a,4,5,6,7,7a-hexahydro-4,7-methano-1H-indenol. The Mw of the polymer (a-5) was 3,000.

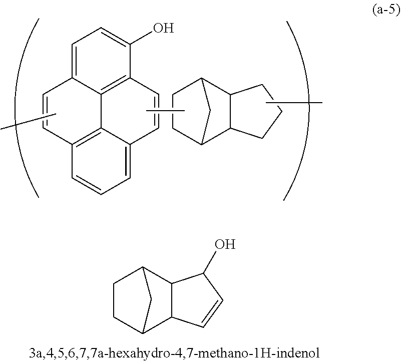

### [Synthesis Example 1-6] (Synthesis of Polymer (a-6))

A polymer (a-6) represented by formula (a-6) was obtained in the same manner as in Synthesis Example 1 except that 5.0 g of 1-hydroxypyrene was changed to 3.4 g of 1-hydroxynaphthalene and 2.0 g of 1,3-adamantanediol was changed to 1.8 g of 3a,4,5,6,7,7a-hexahydro-4,7-methano-1H-indenol. The Mw of the polymer (a-6) was 2,800.

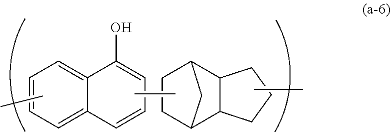

### [Synthesis Example 1-7] (Synthesis of Polymer (a-7))

A polymer (a-7) represented by formula (a-7) was obtained in the same manner as in Synthesis Example 1 except that 5.0 g of 1-hydroxypyrene was changed to 3.7 g of 2,7-dihydroxynaphthalene and 1.9 g of 1,3-adamantanediol was changed to 1.8 g of 3a,4,5,6,7,7a-hexahydro-4,7-methano-1H-indenol. The Mw of the polymer (a-7) was 3,000.

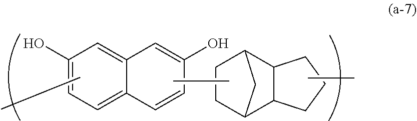

### [Synthesis Example 1-8] (Synthesis of Polymer (a-8))

A polymer (a-8) represented by formula (a-8) was obtained in the same manner as in Synthesis Example 1 except that 5.0 g of 1-hydroxypyrene was changed to 8.2 g of 9,9′-bis(4-hydroxyphenyl)fluorene and 1.9 g of 1,3-adamantanediol was changed to 1.8 g of 3a,4,5,6,7,7a-hexahydro-4,7-methano-1H-indenol. The Mw of the polymer (a-8) was 3,000.

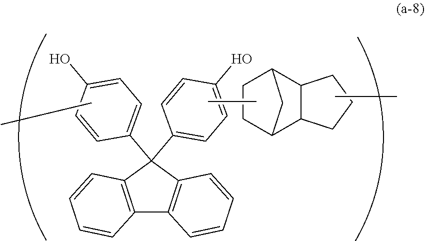

### [Synthesis Example 1-9] (Synthesis of Polymer (a-9))

A polymer (a-9) represented by formula (a-9) was obtained in the same manner as in Synthesis Example 1 except that 5.0 g of 1-hydroxypyrene was changed to 2.6 g of resorcinol and 1.9 g of 1,3-adamantanediol was changed to 1.8 g of 3a,4,5,6,7,7a-hexahydro-4,7-methano-1H-indenol. The Mw of the polymer (a-9) was 2,500.

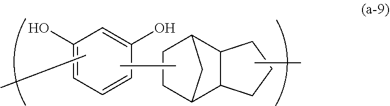

### [Synthesis Example 1-10] (Synthesis of Polymer (a-10))

A polymer (a-10) represented by formula (a-10) was obtained in the same manner as in Synthesis Example 1 except that 1.9 g of 1,3-adamantanediol was changed to 1.1 g of cyclohexanone and 0.7 g of methanesulfonic acid was changed to 0.8 g of trifluoromethanesulfonic acid. The Mw of the polymer (a-10) was 2,000.

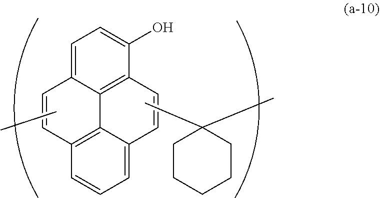

### [Synthesis Example 1-11] (Synthesis of Polymer (a-11))

A polymer (a-11) represented by formula (a-11) was obtained in the same manner as in Synthesis Example 1 except that 5.0 g of 1-hydroxypyrene was changed to 3.2 g of 1-hydroxynaphthalene, 1.9 g of 1,3-adamantanediol was changed to 1.1 g of cyclohexanone, and 0.7 g of methanesulfonic acid was changed to 0.8 g of trifluoromethanesulfonic acid. The Mw of the polymer (a-11) was 2,100.

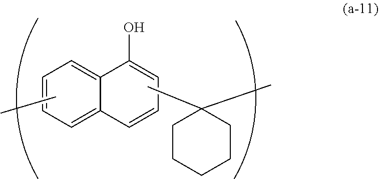

### [Synthesis Example 1-12] (Synthesis of Polymer (a-12))

A polymer (a-12) represented by formula (a-12) was obtained in the same manner as in Synthesis Example 1 except that 5.0 g of 1-hydroxypyrene was changed to 3.6 g of 2,7-dihydroxynaphthalene, 1.9 g of 1,3-adamantanediol was changed to 1.1 g of cyclohexanone, and 0.7 g of methanesulfonic acid was changed to 0.8 g of trifluoromethanesulfonic acid. The Mw of the polymer (a-12) was 2,200.

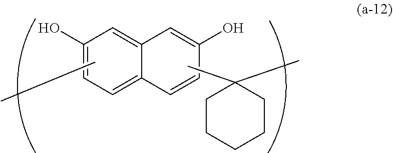

### [Synthesis Example 1-13] (Synthesis of Polymer (a-13))

A polymer (a-13) represented by formula (a-13) was obtained in the same manner as in Synthesis Example 1 except that 5.0 g of 1-hydroxypyrene was changed to 7.8 g of 9,9′-bis(4-hydroxyphenyl)fluorene, 1.9 g of 1,3-adamantanediol was changed to 1.1 g of cyclohexanone, and 0.7 g of methanesulfonic acid was changed to 0.8 g of trifluoromethanesulfonic acid. The Mw of the polymer (a-13) was 2,900.

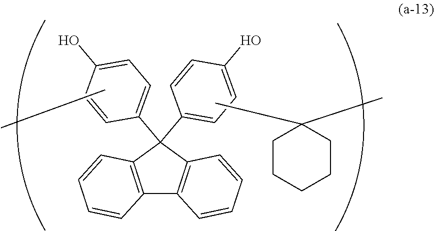

### Synthesis of Polymer [A]

### [Example 1-1] (Synthesis of Polymer (A-1))

In a nitrogen atmosphere, 5.0 g of the polymer (a-1), 2.4 g of propargyl bromide, 75.0 g of methyl isobutyl ketone, and 15.0 g of methanol were added into a reaction vessel and stirred. Then, 9.9 g of a 25% by mass aqueous tetramethylammonium hydroxide solution was added, and the reaction was conducted at 50° C. for 6 hours. The reaction solution was cooled to 30° C., and then 100 g of a 5% by mass aqueous oxalic acid solution was added. After the aqueous phase was separated, the obtained organic phase was washed several times with 200 g of water. The organic phase was concentrated using an evaporator, and the residue was added dropwise into 200 g of methanol to obtain a precipitate. The precipitate was collected by suction filtration and washed several times with 100 g of methanol. Then, the washed product was dried at 60° C. for 12 hours using a vacuum dryer, thereby obtaining a polymer (A-1) represented by formula (A-1). The Mw of the polymer (A-1) was 3,300.

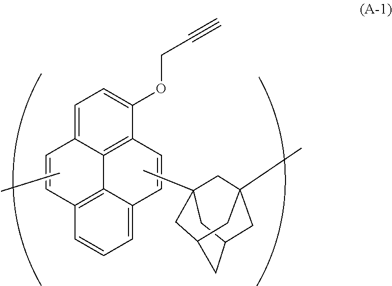

### [Example 1-2] (Synthesis of Polymer (A-2))

A polymer (A-2) represented by formula (A-2) was obtained in the same manner as in Example 1-1 except that 5.0 g of (a-1) was changed to 4.1 g of (a-2). The Mw of the polymer (A-2) was 2,800.

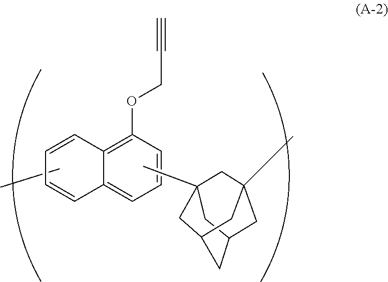

### [Example 1-3] (Synthesis of Polymer (A-3))

A polymer (A-3) represented by formula (A-3) was obtained in the same manner as in Example 1-1 except that 5.0 g of (a-1) was changed to 4.0 g of (a-3), the amount of propargyl bromide was changed from 2.4 g to 4.6 g, and the amount of 25% by mass aqueous tetramethylammonium hydroxide solution was changed from 9.9 g to 18.8 g. The Mw of the polymer (A-3) was 3,000.

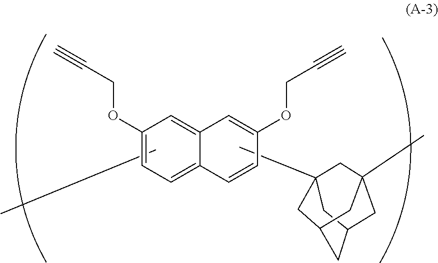

### [Example 1-4] (Synthesis of Polymer (A-4))

A polymer (A-4) represented by formula (A-4) was obtained in the same manner as in Example 1-1 except that 5.0 g of (a-1) was changed to 4.0 g of (a-4), the amount of propargyl bromide was changed from 2.4 g to 4.8 g, and the amount of 25% by mass aqueous tetramethylammonium hydroxide solution was changed from 9.9 g to 11.8 g. The Mw of the polymer (A-4) was 3,950.

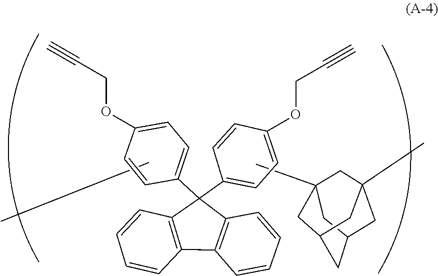

### [Example 1-5] (Synthesis of Polymer (A-5))

A polymer (A-5) represented by formula (A-5) was obtained in the same manner as in Example 1-1 except that 5.0 g of (a-1) was changed to 4.8 g of (a-5). The Mw of the polymer (A-5) was 3,800.

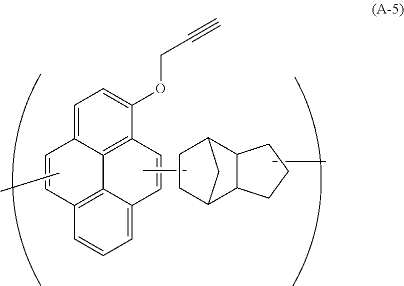

### [Example 1-6] (Synthesis of Polymer (A-6))

A polymer (A-6) represented by formula (A-6) was obtained in the same manner as in Example 1-1 except that 5.0 g of (a-1) was changed to 3.8 g of (a-6). The Mw of the polymer (A-6) was 3,500.

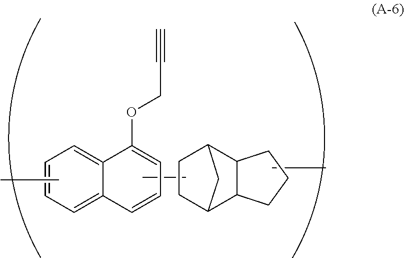

### [Example 1-7] (Synthesis of Polymer (A-7))

A polymer (A-7) represented by formula (A-7) was obtained in the same manner as in Example 1-1 except that 5.0 g of (a-1) was changed to 3.9 g of (a-7), the amount of propargyl bromide was changed from 2.4 g to 4.6 g, and the amount of 25% by mass aqueous tetramethylammonium hydroxide solution was changed from 9.9 g to 18.8 g. The Mw of the polymer (A-7) was 3,900.

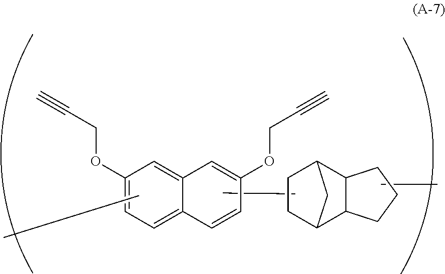

### [Example 1-8] (Synthesis of Polymer (A-8))

A polymer (A-8) represented by formula (A-8) was obtained in the same manner as in Example 1-1 except that 5.0 g of (a-1) was changed to 3.8 g of (a-8), the amount of propargyl bromide was changed from 2.4 g to 2.8 g, and the amount of 25% by mass aqueous tetramethylammonium hydroxide solution was changed from 9.9 g to 11.5 g. The Mw of the polymer (A-8) was 3,900.

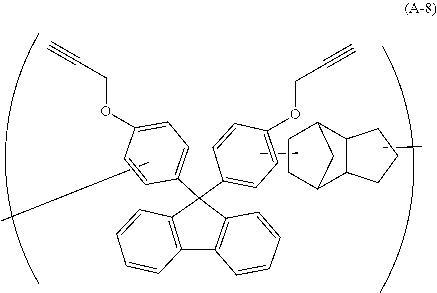

### [Example 1-9] (Synthesis of Polymer (A-9))

A polymer (A-9) represented by formula (A-9) was obtained in the same manner as in Example 1-1 except that 5.0 g of (a-1) was changed to 2.0 g of (a-9), the amount of propargyl bromide was changed from 2.4 g to 3.0 g, and the amount of 25% by mass aqueous tetramethylammonium hydroxide solution was changed from 9.9 g to 12.5 g. The Mw of the polymer (A-9) was 3,200.

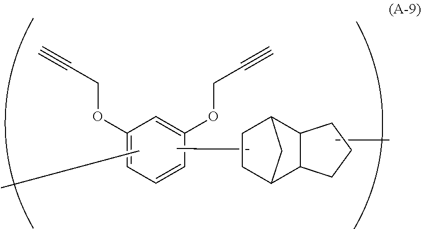

### [Example 1-10] (Synthesis of Polymer (A-10))

A polymer (A-10) represented by formula (A-10) was obtained in the same manner as in Example 1-1 except that 5.0 g of (a-1) was changed to 4.0 g of (a-10). The Mw of the polymer (A-10) was 2,600.

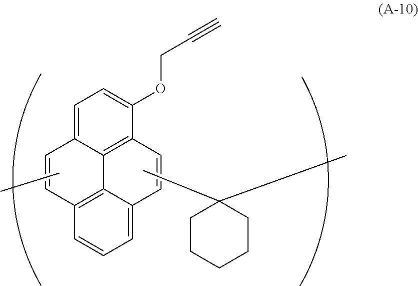

### [Example 1-11] (Synthesis of Polymer (A-11))

A polymer (A-11) represented by formula (A-11) was obtained in the same manner as in Example 1-1 except that 5.0 g of (a-1) was changed to 3.0 g of (a-11). The Mw of the polymer (A-11) was 2,600.

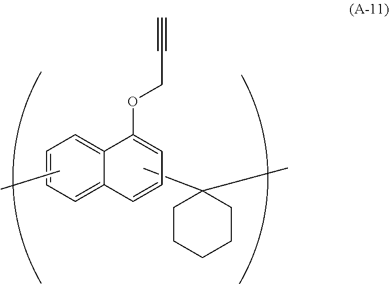

### [Example 1-12] (Synthesis of Polymer (A-12))

A polymer (A-12) represented by formula (A-12) was obtained in the same manner as in Example 1-1 except that 5.0 g of (a-1) was changed to 2.5 g of (a-12), the amount of propargyl bromide was changed from 2.4 g to 3.7 g, and the amount of 25% by mass aqueous tetramethylammonium hydroxide solution was changed from 9.9 g to 15.2 g. The Mw of the polymer (A-12) was 3,600.

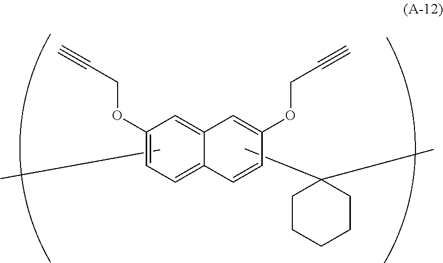

### [Example 1-13] (Synthesis of Polymer (A-13))

A polymer (A-13) represented by formula (A-13) was obtained in the same manner as in Example 1-1 except that 5.0 g of (a-1) was changed to 3.0 g of (a-13), the amount of propargyl bromide was changed from 2.4 g to 2.6 g, and the amount of 25% by mass aqueous tetramethylammonium hydroxide solution was changed from 9.9 g to 11.0 g. The Mw of the polymer (A-13) was 4,200.

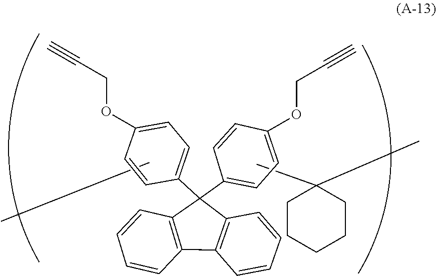

### [Example 1-14] (Synthesis of Polymer (A-14))

A polymer (A-14) represented by formula (A-14) was obtained in the same manner as in Example 1-1 except that 2.4 g of propargyl bromide was changed to 2.5 g of bromoacetonitrile. The Mw of the polymer (A-14) was 3,400.

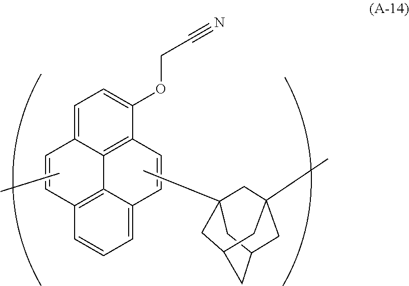

### [Comparative Synthesis Example 1-1] (Synthesis of Polymer (x-1))

In a nitrogen atmosphere, 250.0 g of m-cresol, 125.0 g of 37% by mass formalin, and 2 g of oxalic anhydride were added to a reaction vessel, and the mixture was reacted at 100° C. for 3 hours and at 180° C. for 1 hour, and then unreacted monomers were removed under reduced pressure, affording a polymer (x-1) having a repeating unit represented by formula (x-1). The Mw of the polymer (x-1) obtained was 11,000.

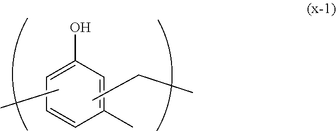

### [Comparative Synthesis Example 1-2] (Synthesis of Polymer (x-2))

In a nitrogen atmosphere, 29.1 g of 2,7-dihydroxynaphthalene, 14.8 g of a 37% by mass formaldehyde solution, and 87.3 g of methyl isobutyl ketone were charged into a reaction and dissolved. After adding 1.0 g of p-toluenesulfonic acid monohydrate to the reaction vessel, and then the mixture was heated to 85° C. and reacted for 4 hours. After completion of the reaction, the reaction solution was transferred to a separatory funnel, 200 g of methyl isobutyl ketone and 400 g of water were added thereto, and the organic phase was washed. After separating the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, thereby obtaining a polymer (x-2) represented by formula (x-2). The Mw of the polymer (x-2) was 3,400.

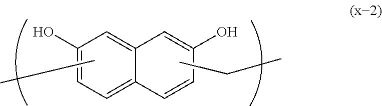

### [Comparative Synthesis Example 1-3] (Synthesis of Polymer (x-3))

In a nitrogen atmosphere, 16.8 g of the polymer (x-2), 34.9 g of propargyl bromide, 90 g of methyl isobutyl ketone, and 45.0 g of methanol were added into a reaction vessel and stirred. Then, 106.9 g of a 25% by mass aqueous tetramethylammonium hydroxide solution was added, and the reaction was conducted at 50° C. for 6 hours. The reaction solution was cooled to 30° C., and then 200.0 g of a 5% by mass aqueous oxalic acid solution was added. After removing the aqueous phase, the obtained organic phase was concentrated with an evaporator, and the residue was added dropwise to 500 g of methanol to obtain a precipitate. The precipitate was collected by suction filtration and washed several times with 100 g of methanol. Then, the washed product was dried at 60° C. for 12 hours using a vacuum dryer, thereby obtaining a polymer (x-3) represented by formula (x-3). The Mw of the polymer (x-3) was 4,500.

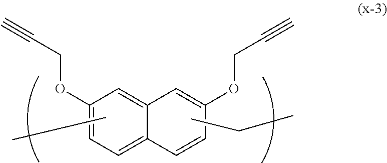

### [Comparative Synthesis Example 4] (Synthesis of Polymer (x-4))

The polymer (x-4) was the same as the polymer (a-2), and a polymer (x-4) was obtained in the same manner as in Synthesis Example 1-2.

### Preparation of Composition

The polymers [A], the solvents [B], the acid generators [C], and the crosslinking agents [D] used for the preparation of compositions are shown below.

### Polymer [A]

Examples: Polymers (A-1) to (A-14) synthesized above

Comparative Examples: Polymer (x-1) and polymer (x-4) synthesized above

### Solvent [B]

B-1: Propylene glycol monomethyl ether acetate

B-2: Cyclohexanone

### Acid Generator [C]

C-1: Bis(4-t-butylphenyl)iodonium nonafluoro-n-butanesulfonate (the compound represented by formula (C-1))

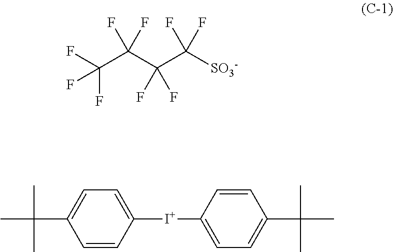

### Crosslinking Agent [D]

D-1: A compound represented by formula (D-1)

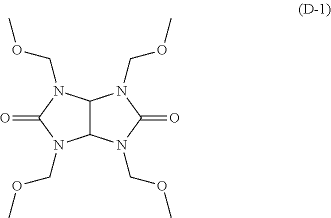 [SMILES: COCN1C(=O)N(COC)C2C1N(COC)C(=O)N2COC]

D-2: A compound represented by formula (D-2)

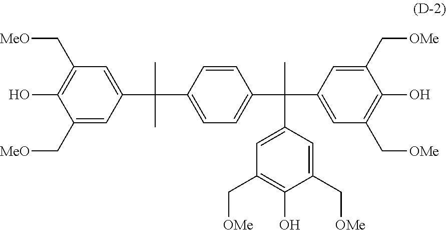 [SMILES: COCc1cc(C(C)(C)c2ccc(C(C)(c3cc(COC)c(O)c(COC)c3)c3cc(COC)c(O)c(COC)c3)cc2)cc(COC)c1O]

### Example 2-1

First, 10 parts by mass of (A-1) as the polymer [A] was dissolved in 90 parts by mass of (B-1) as the solvent [B]. The resulting solution was filtered through a polytetrafluoroethylene (PTFE) membrane filter having a pore size of 0.45 μm to prepare composition (J-1).

### Examples 2-2 to 1-17 and Comparative Examples 2-1 to 2-4

Compositions (J-2) to (J-17) and (CJ-1) to (CJ-4) were prepared in the same manner as in Example 2-1 except that the components of the types and contents shown in the following Table 1 were used. In Table 1, “-” in the columns of “acid generator [C]” and “crosslinking agent [D]” indicates that the corresponding component was not used.

TABLE 1

| | | | | | | Acid generator | | Crosslinking | |
|---|---|---|---|---|---|---|---|---|---|
| | | Polymer [A] | | Solvent [B] | | [C] | | agent [D] | |
| | | | Content | | Content | | Content | | Content |
| | | | (parts by | | (parts by | | (parts by | | (parts by |
| | Composition | Type | mass) | Type | mass) | Type | mass) | Type | mass) |
| Example 2-1 | J-1 | A-1 | 10 | B-1 | 90 | — | — | — | — |
| Example 2-2 | J-2 | A-2 | 10 | B-1 | 90 | — | — | — | — |
| Example 2-3 | J-3 | A-3 | 10 | B-1 | 90 | — | — | — | — |
| Example 2-4 | J-4 | A-4 | 10 | B-1 | 90 | — | — | — | — |
| Example 2-5 | J-5 | A-5 | 10 | B-1 | 90 | — | — | — | — |
| Example 2-6 | J-6 | A-6 | 10 | B-1 | 90 | — | — | — | — |
| Example 2-7 | J-7 | A-7 | 10 | B-1 | 90 | — | — | — | — |
| Example 2-8 | J-8 | A-8 | 10 | B-1 | 90 | — | — | — | — |
| Example 2-9 | J-9 | A-9 | 10 | B-1 | 90 | — | — | — | — |
| Example 2-10 | J-10 | A-10 | 10 | B-1 | 90 | — | — | — | — |
| Example 2-11 | J-11 | A-11 | 10 | B-1 | 90 | — | — | — | — |
| Example 2-12 | J-12 | A-12 | 10 | B-1 | 90 | — | — | — | — |
| Example 2-13 | J-13 | A-13 | 10 | B-1 | 90 | — | — | — | — |
| Example 2-14 | J-14 | A-14 | 10 | B-1 | 90 | — | — | — | — |
| Example 2-15 | J-15 | A-3 | 10 | B-1 | 80 | C-1 | 5 | D-1 | 5 |
| Example 2-16 | J-16 | A-3 | 10 | B-1 | 80 | C-1 | 5 | D-2 | 5 |
| Example 2-17 | J-17 | A-5 | 10 | B-2 | 80 | C-1 | 5 | D-1 | 5 |
| Comparative | CJ-1 | x-1 | 10 | B-1 | 90 | — | — | D-1 | — |
| Example 2-1 | | | | | | | | | |
| Comparative | CJ-2 | x-2 | 10 | B-1 | 90 | — | — | — | — |
| Example 2-2 | | | | | | | | | |
| Comparative | CJ-3 | x-3 | 10 | B-1 | 90 | — | — | — | — |
| Example 2-3 | | | | | | | | | |
| Comparative | CJ-4 | x-4 | 10 | B-1 | 90 | — | — | — | — |
| Example 2-4 | | | | | | | | | |

### Evaluation

Using the compositions obtained above, the heat resistance and bending resistance were evaluated by the methods described below. The evaluation results are shown in the following Table 2.

### Heat Resistance

A composition prepared above was applied to a silicon wafer (substrate) by a spin coating method using a spin coater (“CLEAN TRACK ACT 12” available from Tokyo Electron Limited). Next, the resultant was heated at 200° C. for 60 seconds in the air atmosphere, and then cooled at 23° C. for 60 seconds to form a resist underlayer film having an average thickness of 200 nm, thereby affording a substrate with film, the substrate having the film formed thereon. The film of the substrate with film obtained above was scraped and the resulting powder was collected. The collected powder was placed in a container to be used for measurement with a TG-DTA apparatus (“TG-DTA 2000 SR” manufactured by NETZSCH), and the mass before heating was measured. Next, the powder was heated to 400° C. at a temperature raising rate of 10° C./min in a nitrogen atmosphere using the TG-DTA apparatus, and the mass of the powder at 400° C. was measured. Then, the mass reduction rate (%) was measured from formula, and this mass reduction rate was taken as a measure of heat resistance.

$${M}_{L} = \{ ( m 1 - m 2 ) / m 1 \} \times 100$$

Herein, in the above formula, M_{L} is a mass reduction rate (%), m1 is a mass (mg) before heating, and m2 is a mass (mg) at 400° C.

The smaller the mass reduction rate of the powder to be a sample, the smaller the amount of sublimate or decomposition products of the film generated during heating of the film and the better the heat resistance. That is, the smaller the mass reduction rate, the higher the heat resistance. The heat resistance was evaluated as “A” (extremely good) when the mass reduction rate was less than 5%, “B” (good) when the mass reduction rate was 5% or more and less than 10%, and “C” (poor) when the mass reduction rate was 10% or more.

### Bending Resistance

The composition prepared as described above was applied to a silicon substrate with a silicon dioxide film formed thereon having an average thickness of 500 nm, by a spin coating method using a spin coater (“CLEAN TRACK ACT 12” available from Tokyo Electron Limited). Next, the resultant was heated at 350° C. for 60 seconds in the air atmosphere, and then cooled at 23° C. for 60 seconds, thereby affording a substrate with film, the substrate having thereon a resist underlayer film having an average thickness of 200 nm. A composition for forming a silicon-containing film (“NFC SOG080” manufactured by JSR Corporation) was applied to the resulting substrate with film by a spin coating method, and then heated at 200° C. for 60 seconds in the air atmosphere, and further heated at 300° C. for 60 seconds, thereby forming a silicon-containing film having an average thickness of 50 nm. A resist composition for ArF (“AR1682J” manufactured by JSR Corporation) was applied to the silicon-containing film by a spin coating method, and heated (fired) at 130° C. for 60 seconds in the air atmosphere, thereby forming a resist film having an average thickness of 200 nm. The resist film was exposed with varying an exposure amount through a 1:1 line-and-space mask pattern with a target size of 100 nm using an ArF excimer laser exposure apparatus (lens numerical aperture: 0.78, exposure wavelength: 193 nm), and then heated (fired) at 130° C. for 60 seconds in the air atmosphere, developed at 25° C. for 1 minute using a 2.38% by mass aqueous tetramethylammonium hydroxide (TMAH) solution, washed with water, and dried, thereby affording a substrate on which a 200 nm-pitch line-and-space resist pattern with a line width of the line pattern of 30 nm to 100 nm was formed.

A silicon-containing film was etched using the resist pattern as a mask and using the aforementioned etching apparatus under the conditions of CF₄=200 sccm, PRESS.=85 mT, HF RF (high-frequency power for plasma generation)=500 W, LF RF (high-frequency power for bias)=0 W, DCS=−150 V, and RDC (gas center flow ratio)=50%, thereby affording a substrate on which a pattern was formed on the silicon-containing film. Subsequently, the resist underlayer film was etched using the silicon-containing film pattern as a mask and using the aforementioned etching apparatus under the conditions of O₂=400 sccm, PRESS.=25 mT, HF RF (high-frequency power for plasma generation)=400 W, LF RF (high-frequency power for bias)=0 W, DCS=0 V, and RDC (gas center flow ratio)=50%, thereby affording a substrate on which a pattern was formed on the resist underlayer film. A silicon dioxide film was etched using the resist underlayer film pattern as a mask and using the aforementioned etching apparatus under the conditions of CF₄=180 sccm, Ar=360 sccm, PRESS.=150 mT, HF RF (high-frequency power for plasma generation)=1,000 W, LF RF (high-frequency power for bias)=1,000 W, DCS=−150 V, RDC (gas center flow ratio)=50%, and 60 seconds, thereby affording a substrate on which a pattern was formed on the silicon dioxide film.

Thereafter, for the substrate on which a pattern was formed on a silicon dioxide film, an image was obtained by enlarging the shape of the resist underlayer film pattern of each line width by a magnification of 250,000 times with a scanning electron microscope (“CG-4000” manufactured by Hitachi High-Technologies Corporation), and then the image was subjected to image processing. Thereby, as shown in the FIGURE, for the lateral side surface 3a of the resist underlayer film pattern 3 (line pattern) having a length of 1,000 nm, a value of 3 sigma, which was obtained by multiplying a standard deviation by 3, the standard deviation having been calculated from the positions Xn (n=1 to 10) in the line width direction measured at 10 points at intervals of 100 nm and the position Xa of the average value of those positions in the line width direction, was defined as LER (line edge roughness). The LER, which indicates the degree of bending of a resist underlayer film pattern, increases as the line width of the resist underlayer film pattern decreases. The bending resistance was evaluated as “A” (good) when the line width of the film pattern having an LER of 5.5 nm was less than 40.0 nm, “B” (slightly good) when the line width was 40.0 nm or more and less than 45.0 nm, and “C” (poor) when the line width was 45.0 nm or more. In the FIGURE, the degree of bending of a film pattern is illustrated with exaggeration than actual one.

TABLE 2

| | | Heat | Bending |
|---|---|---|---|
| | Composition | resistance | resistance |
| Example 2-1 | J-1 | A | A |
| Example 2-2 | J-2 | B | B |
| Example 2-3 | J-3 | A | A |
| Example 2-4 | J-4 | A | A |
| Example 2-5 | J-5 | A | A |
| Example 2-6 | J-6 | B | B |
| Example 2-7 | J-7 | A | A |
| Example 2-8 | J-8 | A | A |
| Example 2-9 | J-9 | A | A |
| Example 2-10 | J-10 | B | B |
| Example 2-11 | J-11 | A | A |
| Example 2-12 | J-12 | A | A |
| Example 2-13 | J-13 | A | A |
| Example 2-14 | J-14 | A | A |
| Example 2-15 | J-15 | A | A |
| Example 2-16 | J-16 | A | A |
| Example 2-17 | J-17 | A | A |
| Comparative | CJ-1 | C | C |
| Example 2-1 | | | |
| Comparative | CJ-2 | C | C |
| Example 2-2 | | | |
| Comparative | CJ-3 | C | B |
| Example 2-3 | | | |
| Comparative | CJ-4 | C | B |
| Example 2-4 | | | |

As can be seen from the results in Table 2, the resist underlayer films formed from the compositions of Examples were superior in heat resistance, and bending resistance to the resist underlayer films formed from the compositions of Comparative Examples.

Using the method for manufacturing a semiconductor substrate of the present disclosure, a favorably-patterned substrate can be obtained. By use of the composition of the present disclosure, a resist underlayer film excellent in heat resistance and bending resistance can be formed. The polymer of the present disclosure is suitable for a composition that can be used to form a resist underlayer film excellent in heat resistance and bending resistance. Therefore, they can suitably be used for, for example, producing semiconductor devices expected to be further microfabricated in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, the method comprising:
applying a composition for forming a resist underlayer film directly or indirectly to a substrate to form a resist underlayer film;
forming a resist pattern directly or indirectly on the resist underlayer film; and
performing etching using the resist pattern as a mask,
wherein the composition for forming a resist underlayer film comprises:
a polymer comprising a repeating unit represented by formula (1); and
a solvent: 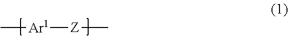
in the formula (1), Ar¹ is a divalent group having an aromatic ring structure having 5 to 40 ring atoms, Z is a divalent group having an alicyclic structure having 3 to 20 carbon atoms, and at least one of Ar¹ or Z comprises at least one group selected from the group consisting of a group represented by formula (2-1) and a group represented by formula (2-2), 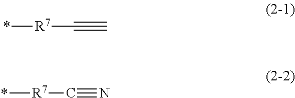
in the formulas (2-1) and (2-2), R⁷ is each independently a divalent organic group having 1 to 20 carbon atoms or a single bond, and * is a bond with another structure in the polymer.

2. The method for manufacturing a semiconductor substrate according to claim 1, wherein
Z in the formula (1) is represented by formula (A): 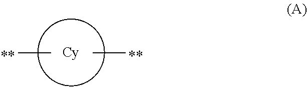
in the formula (A), Cy is the alicyclic structure, and ** are each a bond, which extends from a carbon atom constituting the alicyclic structure, with another structure in the polymer.

3. The method for manufacturing a semiconductor substrate according to claim 1, further comprising forming a silicon-containing film directly or indirectly on the resist underlayer film before forming the resist pattern.

4. A composition comprising:
a polymer comprising a repeating unit represented by formula (1); and
a solvent: 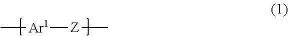
in the formula (1), Ar¹ is a divalent group having an aromatic ring structure having 5 to 40 ring atoms, Z is a divalent group having an alicyclic structure having 3 to 20 carbon atoms, and at least one of Ar¹ or Z comprises at least one group selected from the group consisting of a group represented by formula (2-1) and a group represented by formula (2-2), 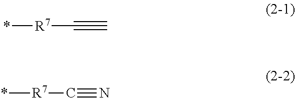
in the formulas (2-1) and (2-2), R⁷ is each independently a divalent organic group having 1 to 20 carbon atoms or a single bond, and * is a bond with another structure in the polymer.

5. The composition according to claim 4, wherein
Z in the formula (1) is represented by formula (A): 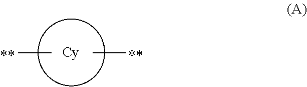
in the formula (A), Cy is the alicyclic structure, and ** are each a bond, which extends from a carbon atom constituting the alicyclic structure, with another structure in the polymer.

6. The composition according to claim 4, wherein the aromatic ring structure of Ar¹ is at least one aromatic hydrocarbon ring selected from the group consisting of a benzene ring, a naphthalene ring, an anthracene ring, a phenalene ring, a phenanthrene ring, a pyrene ring, a fluorene ring, a perylene ring, and a coronene ring.

7. The composition according to claim 4, wherein the alicyclic structure of Z is at least one alicyclic hydrocarbon ring selected from the group consisting of a cyclobutane ring, a cyclopentane ring, a cyclohexane ring, a norbornane ring, an adamantane ring, a bicyclooctane ring, and a tetrahydrodicyclopentadiene ring.

8. The composition according to claim 4, wherein at least one of the aromatic ring structure or the alicyclic structure comprises a polycyclic structure.

9. The composition according to claim 4, wherein the Ar¹ comprises at least one group selected from the group consisting of a group represented by the formula (2-1) and a group represented by the formula (2-2).

10. The composition according to claim 4, wherein the Ar¹ comprises two or more groups selected from the group consisting of a group represented by the formula (2-1) and a group represented by the formula (2-2).

11. The composition according to claim 4, wherein
the Ar¹ comprises a group represented by the formula (2-1), and the group is represented by formula (2-1-1) or (2-1-2): 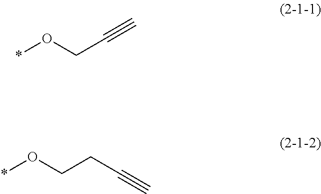
in the formula (2-1-1) or formula (2-1-2), * is a bond with a carbon atom constituting the aromatic ring structure.

12. The composition according to claim 4, which is suitable for forming a resist underlayer film.

13. A polymer comprising a repeating unit represented by formula (1): 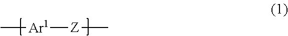
in the formula (1), Ar¹ is a divalent group having an aromatic ring structure having 5 to 40 ring atoms, Z is a divalent group having an alicyclic structure having 3 to 20 carbon atoms, and at least one of Ar¹ or Z has at least one group selected from the group consisting of a group represented by formula (2-1) and a group represented by formula (2-2), 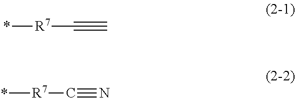
in the formulas (2-1) and (2-2), R⁷ is each independently a divalent organic group having 1 to 20 carbon atoms or a single bond, and * is a bond with another structure in the polymer.
